(19) United States
(12) Patent Application Publication
(10) Pub. No.: US 2013/0342894 A1
(43) Pub. Date: Dec. 26, 2013

(54) Wavelength Conversion Laser System

(71) Applicant: Ytel Photonics Inc, Gwangju (KR)

(72) Inventor: Yong Tak Lee, Gwangju-si (KR)

(73) Assignee: Ytel Photonics Inc., Gwangju (KR)

(21) Appl. No.: 13/975,177

(22) Filed: Aug. 23, 2013

Related U.S. Application Data
(63) Continuation-in-part of application No. 13/146,911, filed on Jul. 28, 2011, now abandoned.

(51) Int. Cl. H01S 5/00; H01S 3/10

(52) U.S. Cl. CPC H01S 5/0078; H01S 3/10023
USPC 359/337.2; 359/568

(57) ABSTRACT

The present invention relates to a wavelength conversion laser system and provides a wavelength conversion laser system including a semiconductor optical amplifier, an optical condenser that condenses light emitted from the optical amplifier, a diffraction grating plate that induces wavelength components of the light having passed through the optical condenser in different directions, and an optical very large scale integration (VLSI) processor.

### CROSS-REFERENCE TO RELATED APPLICATIONS

This application is a Continuation-in-Part application of U.S. application Ser. No. 13/146,911, filed on Jul. 28, 2011, which is a National Phase of International Application No. PCT/KR2009/000397, which was filed on Jan. 28, 2009, the disclosure of which is hereby incorporated herein by reference in its entirety.

### BACKGROUND

1. Field of the Invention

The present invention relates to a wavelength conversion laser system, and more particularly, to a wavelength conversion laser system using an optical very large scale integration (VLSI) processor.

2. Discussion of Related Art

A source of a wavelength conversion laser is an important component for constructing an optical communication network based on a wavelength division modulation (WDM). This is because a wavelength-convertible laser source has maximum wavelength selection flexibility and more efficient use as a wavelength resource.

A wavelength conversion laser has wavelength selectivity and thus has been widely used, for example, for WDM-based optical communication. Examples of an existing wavelength conversion laser include a solid-state laser, a chemical dye laser, and the like. However, the existing wavelength conversion lasers are large in a change in noise according to a variation in pump power and require a large-scaled, complicated pumping system, and thus they are difficult to apply to an actual environment.

For this reason, in designing a wavelength conversion laser system, a great effort has been made to find laser media which makes a broad emission band possible. However, the solid-state laser and the chemical dye laser that can bring a continuous wave (CW) wavelength conversion have been actually developed to satisfy a substantive necessary condition.,

These systems have shortcomings in that inherent noise according to a variation in pump power or dye jet is large and a complicated pump system is required. These shortcomings increase the volume of the system and lead to susceptibility to environmental influence.

### SUMMARY OF THE INVENTION

The present invention is directed to a wavelength conversion laser system in which wavelength conversion is performed by a very simple configuration using a semiconductor optical amplifier, a super luminescent diode (SLD), an optical VLSI processor, or the like, a structure is simple, and a manufacturing cost is low.

According to an aspect of the present invention, there is provided a wavelength conversion laser system, including: a semiconductor optical amplifier; an optical condenser that condenses light emitted from the optical amplifier; a diffraction grating plate that induces wavelength components of the light having passed through the optical condenser in different directions; and an optical very large scale integration (VLSI) processor that applies an electric current through a data decoder and an address decoder and forms a desired hologram pattern, thereby causing a specific wavelength of the light of the induced wavelength components to be returned to the semiconductor optical amplifier.

The wavelength conversion laser system may further include an output port for emitting the light of the specific wavelength which has been returned to the optical condenser and amplified by the semiconductor optical amplifier to the outside.

According to another aspect of the present invention, there is provided a wavelength conversion laser system, including: a light source; an optical condenser that condenses light emitted from the light source; a diffraction grating plate that induces wavelength components of the light having passed through the optical condenser in different directions; an optical very large scale integration (VLSI) processor that applies an electric current through a data decoder and an address decoder and forms a desired hologram pattern, thereby causing a specific wavelength of the light of the induced wavelength components to be returned to the light source; and an optical coupler that is installed between the light source and the optical condenser and splits the light returned from the optical VLSI processor.

The optical coupler may include one input port and two output ports, wherein the input port is connected to the optical condenser, one of the two output ports is connected to a light-emitting diode (LED), and the other of the two output ports functions as an actual output part.

One of the two output ports may be connected to a plurality of light sources (for example, LEDs) having different wavelength ranges.

A super luminescent diode (SLD) or an erbium doped fiber laser (EDFL) may be used as the light source.

According to the present invention, since wavelength conversion can be performed by a very simple configuration using a semiconductor optical amplifier and an optical VLSI processor, a system is inexpensive and can be scaled down. Further, since only light of a specific wavelength is emitted through the optical VLSI processor, wavelength conversion can be performed with a high degree of accuracy.

According to the present invention, in order to vary a wavelength, an arbitrary narrow band of a broad amplified spontaneous emission (ASE) spectrum generated by the semiconductor optical amplifier is coupled with an active resonance structure of the semiconductor optical amplifier for the sake of amplification using an optimized phase hologram loaded on the optical VLSI processor.

Further, the present invention provides an effect capable of achieving stable laser performance by a wavelength variable range of, for example, 10 nm by changing a phase hologram of the optical VLSI processor.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a schematic configuration diagram of a wavelength conversion system according to a first embodiment of the present invention;

FIG. 2 is a detailed diagram of an optical VLSI processor 160 of FIG. 1;

FIG. 3 is a diagram for explaining a relation between a phase level and the number of pixels for the sake of blazed grating analysis by an optical VLSI processor of FIG. 2;

FIG. 4 is a diagram for explaining steering of a blazed hologram of various corresponding pixel blocks;

FIG. 5 is a diagram for explaining the principle of beam steering using an optical VLSI processor;

FIG. 6 illustrates an actual experimental configuration according to the first embodiment of the present invention;

FIG. 7 is a photograph illustrating the experimental configuration

FIG. 8 is a graph illustrating a spectrum of a broadband ASE generated by a semiconductor optical amplifier;

FIGS. 9A to 9C are diagrams illustrating digital phase holograms for selecting a specific wavelength;

FIG. 10 illustrates an output spectrum measured to implement single wavelength selection through hologram optimization;

FIG. 11 is a schematic configuration diagram of a wavelength variable laser system according to a second embodiment of the present invention; and

FIG. 12 is a schematic configuration diagram illustrating a modification of the wavelength conversion laser system according to the second embodiment of the present invention;

FIG. 13 is show one example of MEMS micro mirror.

### DETAILED DESCRIPTION OF EXEMPLARY EMBODIMENTS

Exemplary embodiments of the present invention will be described in detail below with reference to the accompanying drawings. While the present invention is shown and described in connection with exemplary embodiments thereof, it will be apparent to those skilled in the art that various modifications can be made without departing from the spirit and scope of the invention.

### Wavelength Conversion System Using Semiconductor Optical Amplifier And Optical-VLSI

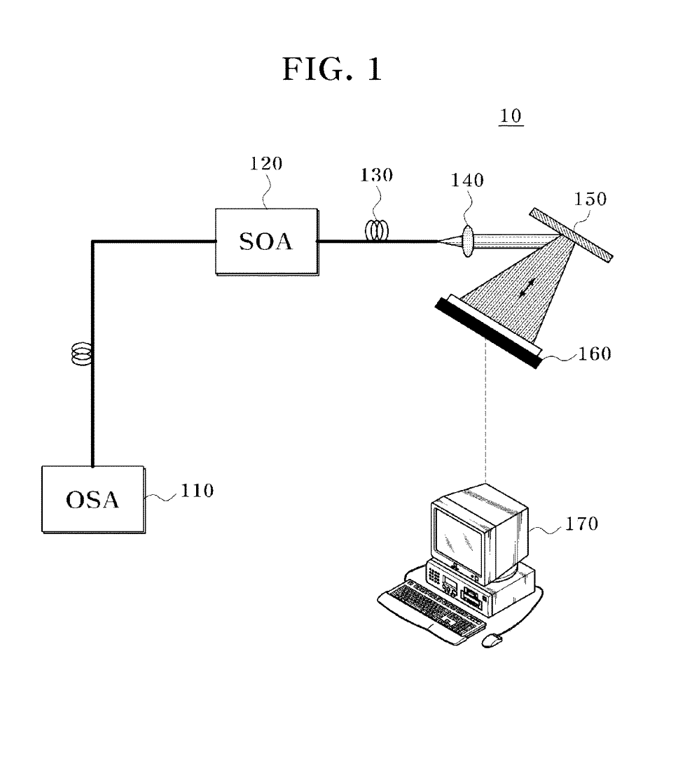

FIG. 1 is a schematic configuration diagram of a wavelength conversion system according to a first embodiment of the present invention.

Referring to FIG. 1, a wavelength conversion laser system 10 includes an optical spectrum analyzer (OSA) 110, a semiconductor optical amplifier (SOA) 120, an optical condenser (collimator) 140, a diffraction grating plate 150, and an optical VLSI processor 160.

Broad amplified spontaneous emission (ASE) light emitted and amplified by the semiconductor optical amplifier 120 is incident to the optical condenser 140. The light condensed through the optical condenser 140 is applied to the optical VLSI processor 160 through the diffraction grating plate 150.

The diffraction grating plate 150 plays a role of sending wavelength components of the condensed light in different directions toward the optical VLSI processor 160. The optical VLSI processor 160 forms a desired diffraction grating pattern and induces light of a specific wavelength to pass through the optical condenser 140 again. The optical VLSI processor 160 will be described in detail later.

The light of the specific wavelength having passed through the optical condenser 140 is amplified by the semiconductor optical amplifier 120 and emitted to the outside. That is, since only light of a desired wavelength is emitted, wavelength conversion can be implemented. At this time, the optical spectrum analyzer 110 plays a role of analyzing light emitted to the outside.

The optical VLSI processor 160 functions to return only the specific wavelength of the light of the induced wavelength components to the semiconductor optical amplifier. The function of returning the specific wavelength can be implemented by applying an electric current through a data decoder and an address decoder to thereby form a hologram pattern.

A polarization controller 130 may be optically installed and plays a role of adjusting polarization necessary for the system.

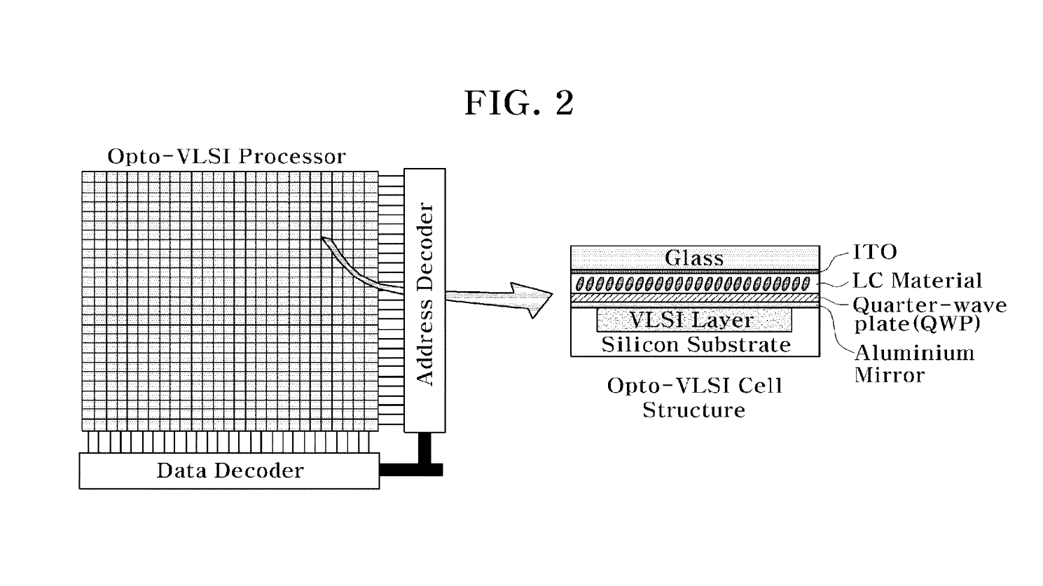

FIG. 2 is a detailed diagram of the optical VLSI processor 160 of FIG. 1.

Referring to FIG. 2, an aluminum mirror, a quarter-wave plate (QWP), a liquid crystal (LC) material, indium tin oxide (ITO), and glass are sequentially stacked on a silicon substrate. An electric current is applied through a data decoder and an address decoder, so that a hologram pattern is formed.

When light is applied to the optical VLSI processor 160 having the above configuration, the light is diffracted by the hologram pattern formed by the optical VLSI processor 160. An angle of the light is decided as in θ=λ(q×d), where λ is a wavelength of incident light, q is the number of pixels per unit interval, and d is a pixel diameter.

In further detail, the optical VLSI processor 160 generates a digital holographic diffraction grating capable of adjusting a direction of an optical beam or forming an optical beam. Each pixel is allocated to a predetermined memory device for storing a digital value and allocated to a multiplexer for selecting a certain input voltage value or applying a selected voltage value to an aluminum mirror.

The optical VLSI processor 160 is connected to a personal computer 170 or the like and electronically controlled. The optical VLSI processor 160 may be configured with software and is independent of polarization. The optical VLSI processor 160 can control a plurality of optical beams at the same time. Further, mass production of a VLSI chip is possible, and thus the price is low. Furthermore, the optical VLSI processor 160 is high in reliability. This is because beam steering is provided without a mechanically operated part. For these reasons, the optical VLSI technique is attracting public attention as a technique for a reconfigurable optical network.

FIG. 2 illustrates an exemplary structure of the optical VLSI processor. The ITO layer is used as a transparent electrode, and the aluminum mirror is used as a reflective electrode. The thin quarter-wave plate is interposed between the LC material and the back surface of the VLSI. In this case, an optical VLSI processor insensitive to polarization can be implemented. The ITO layer is usually grounded. A voltage is applied to the reflective electrode by a VLSI circuit below the LC material so that a stepwise blazed grating can be generated.

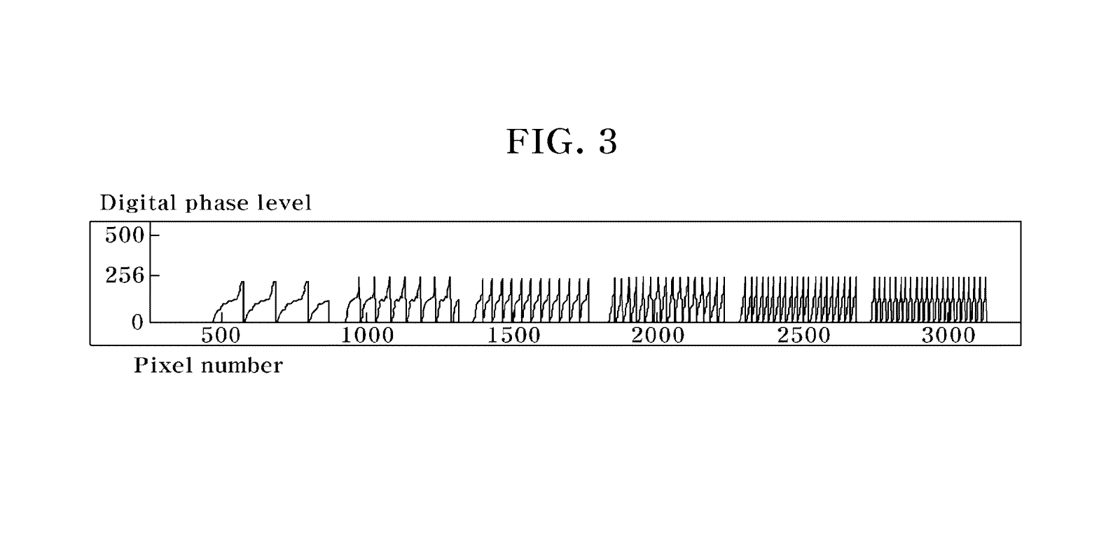

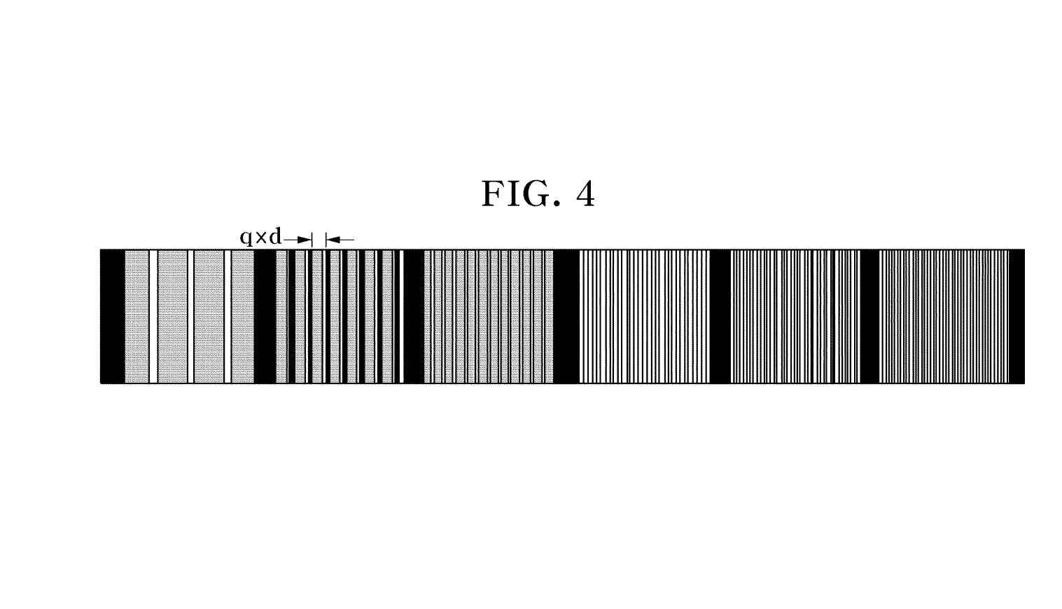

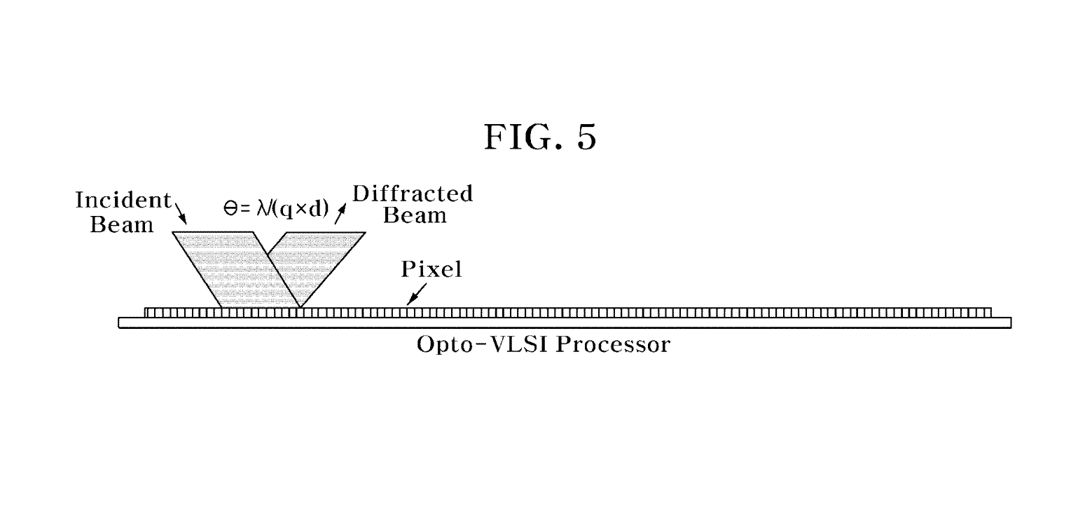

FIGS. 3 to 5 illustrate steering performance of an optical VLSI processor having a pixel size of “d.” It is driven by a blazed grating according to a phase hologram (FIG. 4). FIG. 3 is a diagram for explaining a relation between a phase level and the number of pixels for the sake of blazed grating analysis by the optical VLSI processor of FIG. 2. FIG. 4 is a diagram for explaining steering of a blazed hologram of various corresponding pixel blocks. FIG. 5 is a diagram for explaining the principle of beam steering using an optical VLSI processor.

If a pitch of a blazed grating is “q×d” (here, q represents the number of pixels per pitch), an optical beam is steered by an angle “θ” which is in proportion to a wavelength λ of light and in reverse proportion to “q×d” as illustrated in FIG. 5.

A blazed grating of an arbitrary pitch can be generated, for example, using MATLAB or Labview software by changing a voltage applied to each pixel and digitally driving a block of pixels with appropriate phase levels. Further, an incident optical beam is dynamically emitted in an arbitrary direction.

### Experimental Example

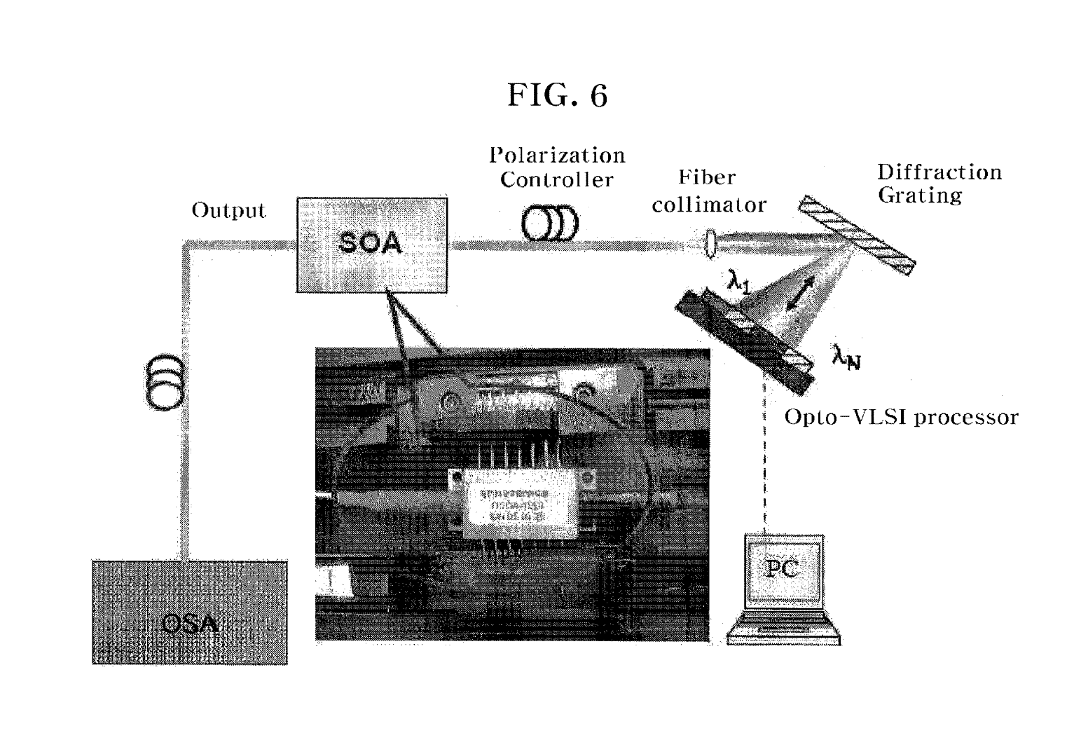

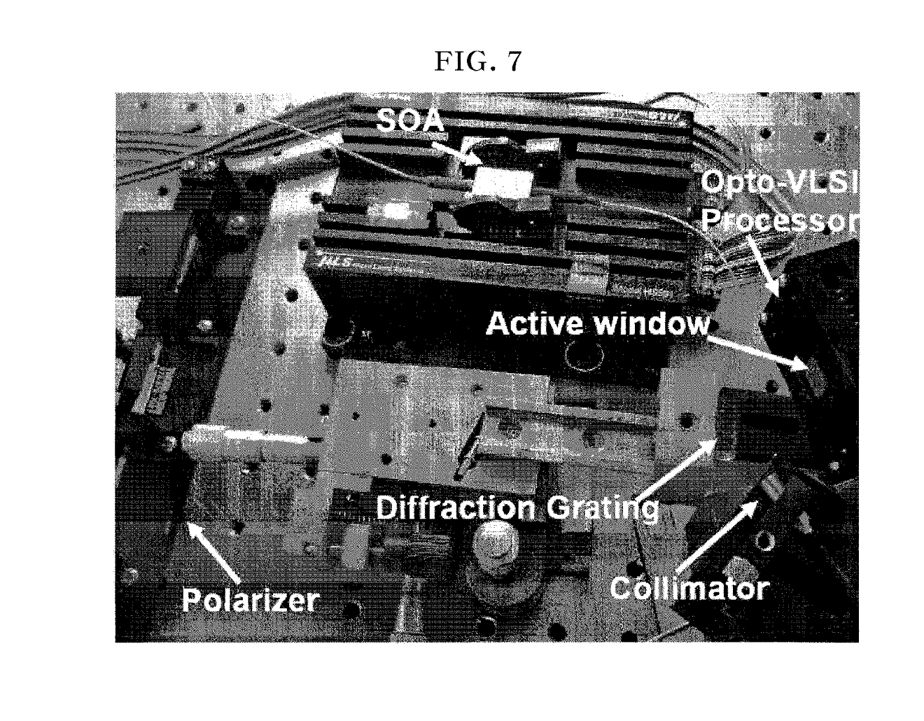

FIG. 6 illustrates an actual experimental configuration according to a first embodiment of the present invention. FIG. 7 is a photograph showing the experimental configuration.

It can be seen that a wavelength conversion laser system of FIG. 6 includes a semiconductor optical amplifier, an optical condenser (collimator), a diffraction grating plate, and an optical VLSI processor.

The optical amplifier used for the experiment is an off-the-self semiconductor optical amplifier manufactured by Qphotonics. The semiconductor optical amplifier is driven by a Newport Modular Controller Model 8000, and a driving current is 400 mA.

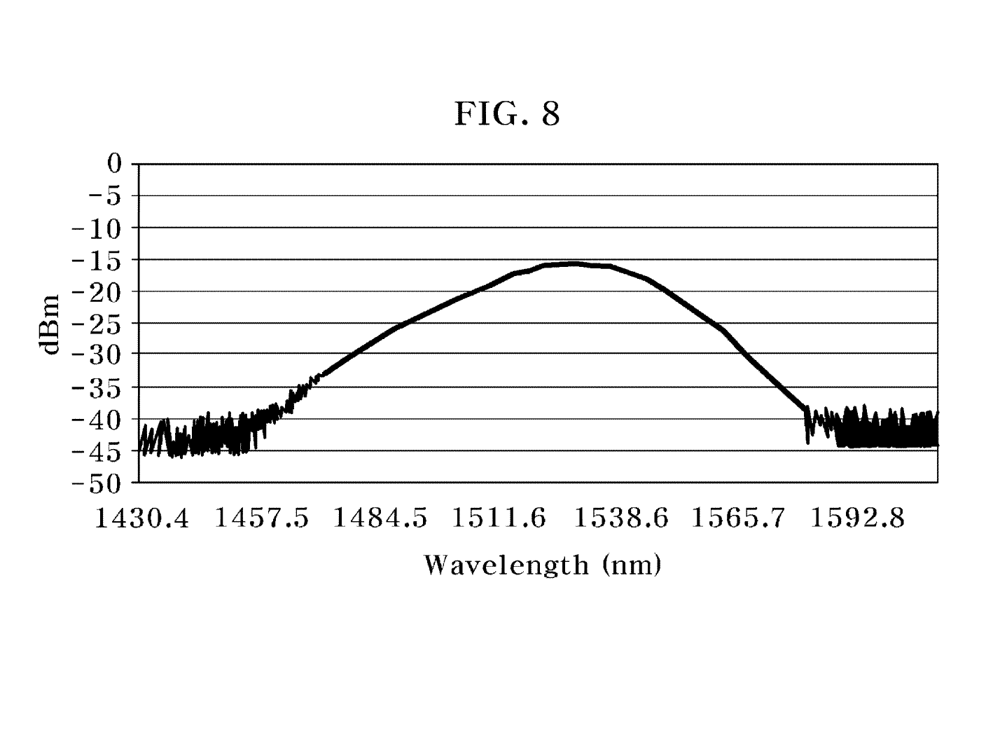

FIG. 8 is a graph showing a spectrum of a broadband ASE generated by the semiconductor optical amplifier. The broadband ASE is condensed using a fiber optical condenser with the diameter of 1 mm. The condensed light is oscillated toward a diffraction grating plate of 1200 lines/mm. The diffraction grating plate diffuses wavelength components of the condensed light in different directions and performs mapping of wavelength components on an active window of the optical VLSI processor.

The optical VLSI processor used for this experiment includes 1×4096 pixels with the pixel size of 1 μm and 256 phase levels, and a dead space of 0.8 μm is present between pixels.

The LabView software was used for generating an optimized digital hologram. The optimized hologram independently steers a wavelength component which is incident in an arbitrary direction.

In order to prove the principle of a proposed wavelength-convertible laser structure, an investigation was made with a three-month scenario. The optical VLSI processor loads a digital phase hologram, and the digital phase hologram minimizes attenuation and returns wavelengths such as 1524.8 nm, 1527.1 nm, and 1532.5 nm to a collimator for coupling.

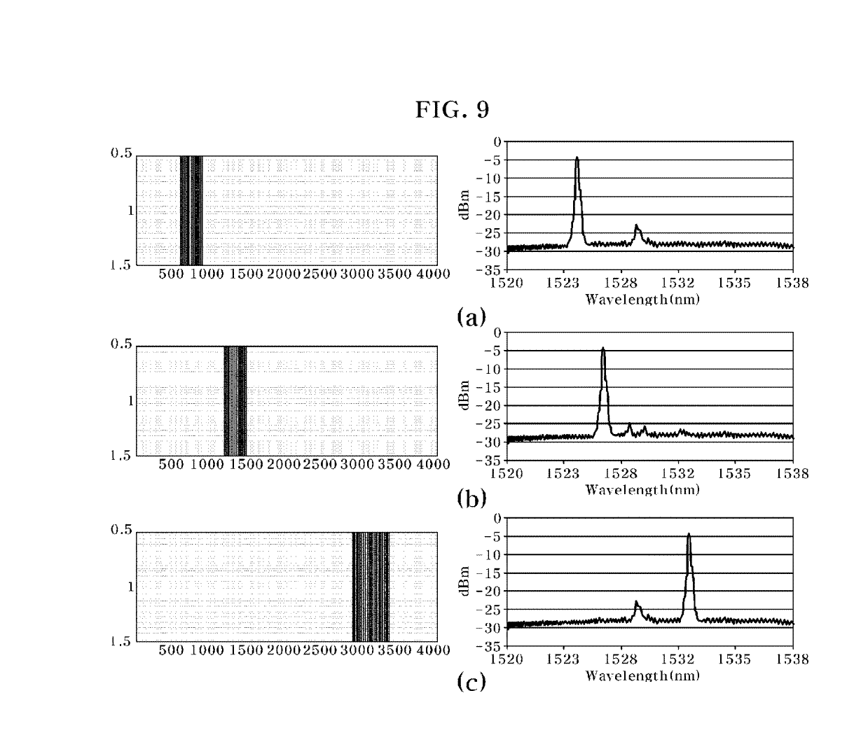

FIGS. 9A to 9C illustrate digital phase holograms for selecting a specific wavelength and semiconductor optical amplifier output spectrums respectively measured on selected wavelengths.

In FIGS. 9A to 9C, a concept of laser wavelength conversion using a characteristic of an optical VLSI processor is proved, and it can be seen that it is possible to steer a specific wavelength and to return the specific wavelength to be coupled with an optical amplifier active resonance structure. Referring to FIGS. 9A to 9C, it can be seen that an output of 20 dB or less is generated at 1529 nm except for output wavelengths, which is caused by a low power zeroth order diffraction beam amplified by a semiconductor optical amplifier cavity.

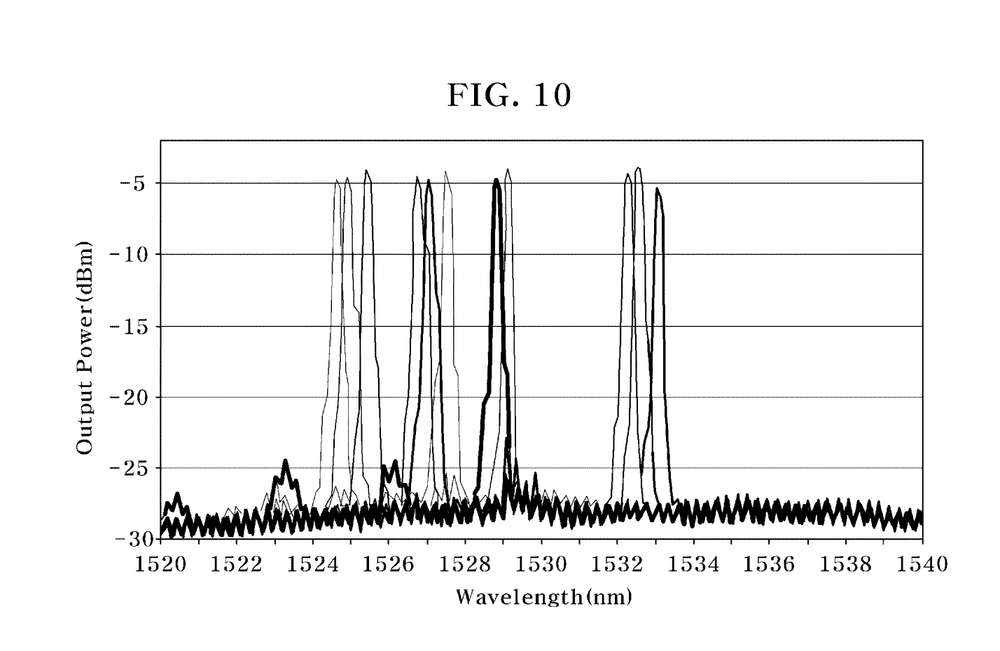

FIG. 10 illustrates an output spectrum measured to realize single wavelength selection through hologram optimization. A wavelength conversion range of 10 nm can be obtained by a used optical VLSI processor, and an active window has the size of about 7.3 mm.

FIG. 8 illustrates that it is important that a 3-dB bandwidth measured in an ASE spectrum of the semiconductor optical amplifier be about 40 nm. Attention should be paid to the fact that expansion of a wavelength conversion range depends on a broadband spectrum of a semiconductor optical amplifier, the size of the active window, a pitch of the grating plate, and the like. Thus, by using an optical VLSI processor having the active window with the size of 20 nm and the blazed grating plate of 600 lines/mm, a wavelength conversion range of 40 nm can be achieved.

In order to implement wavelength conversion, an arbitrary narrow wave band of a broadband ASE spectrum generated by a semiconductor optical amplifier is coupled with an active resonance structure of a semiconductor optical amplifier for the sake of amplification using an optimized phase hologram loaded on an optical VLSI processor.

In the present invention, it has been confirmed that stable laser performance, for example, by a wavelength variable range of 10 nm, can be achieved by changing a phase hologram of an optical VLSI processor.

As illustrated in FIG. 1, the wavelength conversion laser system according to the present embodiment is based on use of the optical VLSI processor as a wavelength-convertible optical filter and the semiconductor optical amplifier as a gain medium.

An optimized digital hologram is generated to independently steer incident wavelength components in arbitrary directions. Attenuation of the specific wavelength is minimized through beam steering, and then the specific wavelength can be coupled with a fiber optical condenser. However, the other wavelengths deviate from a course and so are attenuated.

The coupled wavelength is injected to the inside of the semiconductor optical amplifier and amplified, so that an output optical signal having high amplitude is generated. The wavelength conversion is achieved by changing a phase hologram uploaded onto the optical VLSI processor.

### Wavelength Variable Laser System Using SLD And Optical VLSI

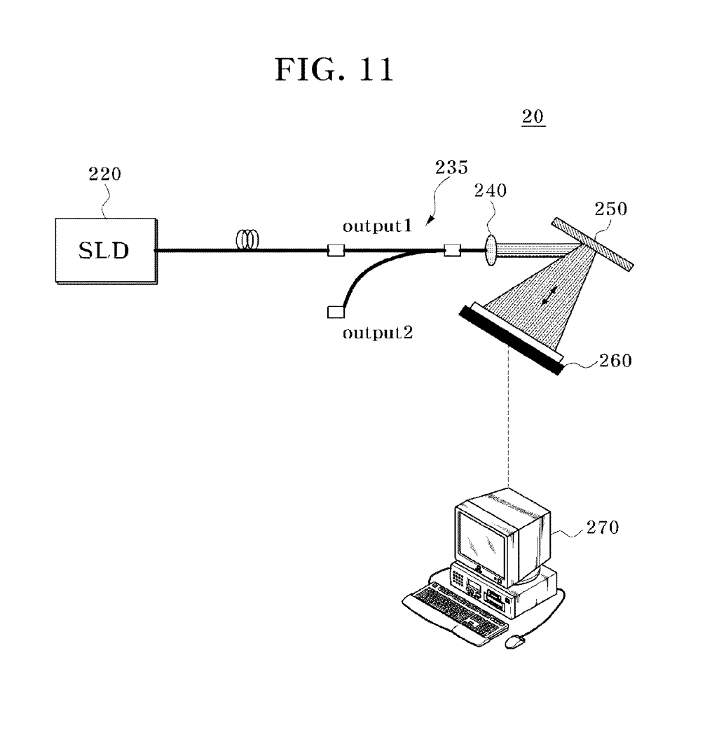

FIG. 11 is a schematic configuration diagram of a wavelength variable laser system according to a second embodiment of the present invention.

Referring to FIG. 11, a wavelength conversion laser system 20 includes a light-emitting diode (LED) 220, an optical coupler 235, an optical condenser (collimator) 240, a diffraction grating plate 250, and an optical VLSI processor 260.

The second embodiment is different from the first embodiment in that the LED is provided instead of the semiconductor optical amplifier 120, and the optical coupler 235 is provided. Preferably, a super luminescent diode (SLD) is used as the LED 220. The SLD 220 is a light-emitting element having high brightness of a laser diode and low coherence of an LED.

According to the present embodiment, the optical coupler 235 is installed between the LED 220 and the optical condenser 240 and splits light returned from the optical VLSI processor 260. Preferably, a 2 by 1 coupler is used as the optical coupler 235. When light is input to an input port of the optical coupler 235, light is split at a desired ratio such as 5:95 or 50:50. In the configuration according to the present embodiment, light is input through one of two output ports. That is, when light is input to an output port output1, light does not enter an output port output2, and most of it is incident to an input port. Thereafter, part of light returned through the optical VLSI processor 260 is input to the output port output1, and part of the light is input to the output port output2. In the case of a configuration in which more light is input to the output port output2 (for example, 95% is input to the output port output2, and 5% is input to the output port output1), most of the light is input to the output port output2.

Thus, referring to FIG. 11, the optical coupler 235 has one input port and two output ports. The input port is connected to the optical condenser 240, and one of the two output ports is connected to the LED 220.

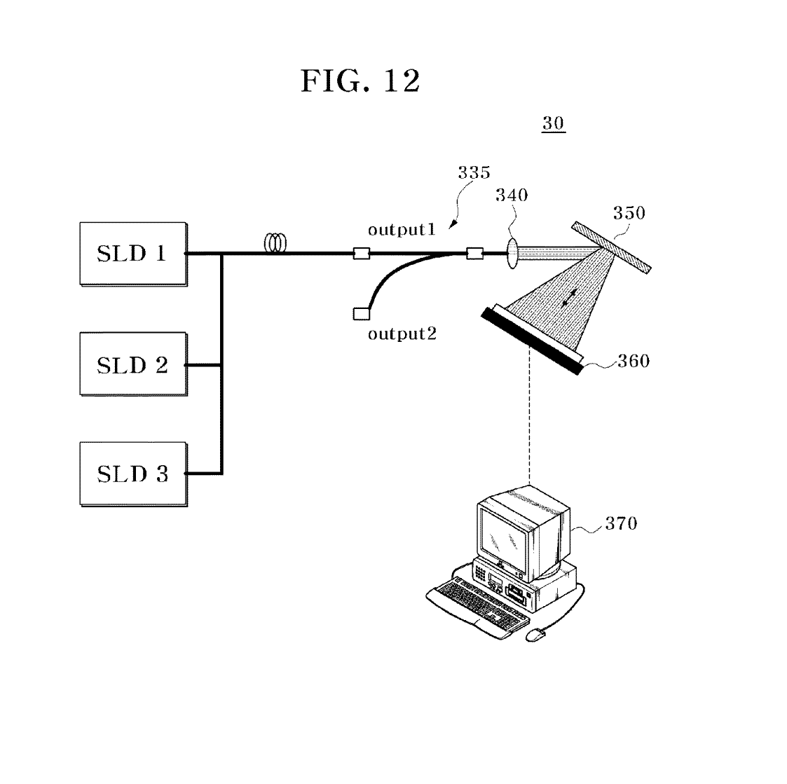

FIG. 12 is a schematic configuration diagram illustrating a modification of a wavelength conversion laser system according to the second embodiment. Referring to FIG. 12, a plurality of LEDs 220 are connected to an input of the optical coupler 235.

In this case, the optical coupler 234 has one input port and a plurality of output ports. The input port is connected to the optical condenser 240, and the plurality of output ports are connected to the plurality of LEDs, respectively. The LEDs may be configured such that At least two of them have different wavelength ranges from each other.

According to this structure, there is an effect that a wavelength band can be configured more broadly, and thus it is more effective for the wavelength conversion laser system.

According to the present embodiment, there is an effect that an input part and an output part can be separated, a structure can be simplified, and a light source can be easily attached to or detached from.

When the optical amplifier is used, the input part is the same as the output part. This difference may not be obvious through the drawings. However, when this configuration is actually implemented as a system, if the input part is separated from the output part, the system can be further simplified. Further, since the input part is separated from the output part, a light source is attachable or detachable, and thus an LED (for example, an SLD) of a desired wavelength can be mounted.

Furthermore, compared to the case in which several SLDs are mounted at the same time, there is an advantage that a wavelength can be varied to a wider wavelength. When the optical VLSI is used, a wavelength variable range depends on a spectrum distribution of an SLD or an optical amplifier (see FIG. 8), and compared to the case in which several SLDs having different wavelengths are mounted at the same time, wavelength selectivity for a wider wavelength is given.

Meanwhile, instead of the SOA of FIG. 1, 6, SLD of FIG. 11, 12, optical fiber amplifier such as an erbium doped fiber laser (EDFL) may be used. When the optical amplifier is used, wavelength tunable (variable) range can be wide and high power can be achieved, compared to SOA.

Furthermore, instead of the optical-VLSIs 160, 260, 360 of FIG. 1, 5, 6, 7, 11, or 12, MEMS (Micro-Electro-Mechanical Systems) mirrors can be used. The main function of MEMS mirrors is similar to that of the optical-VLSIs as mentioned before. Compared to optical-VLSIs, MEMS mirrors has some advantages that MEMS mirrors don't have polarization dependency and is more effectively operable than optical-VLSI in high power operation. In the embodiment, Commercialized MEMS mirrors can be adapted. The cost level of MEMS mirrors is similar to that of optical-VLSI.

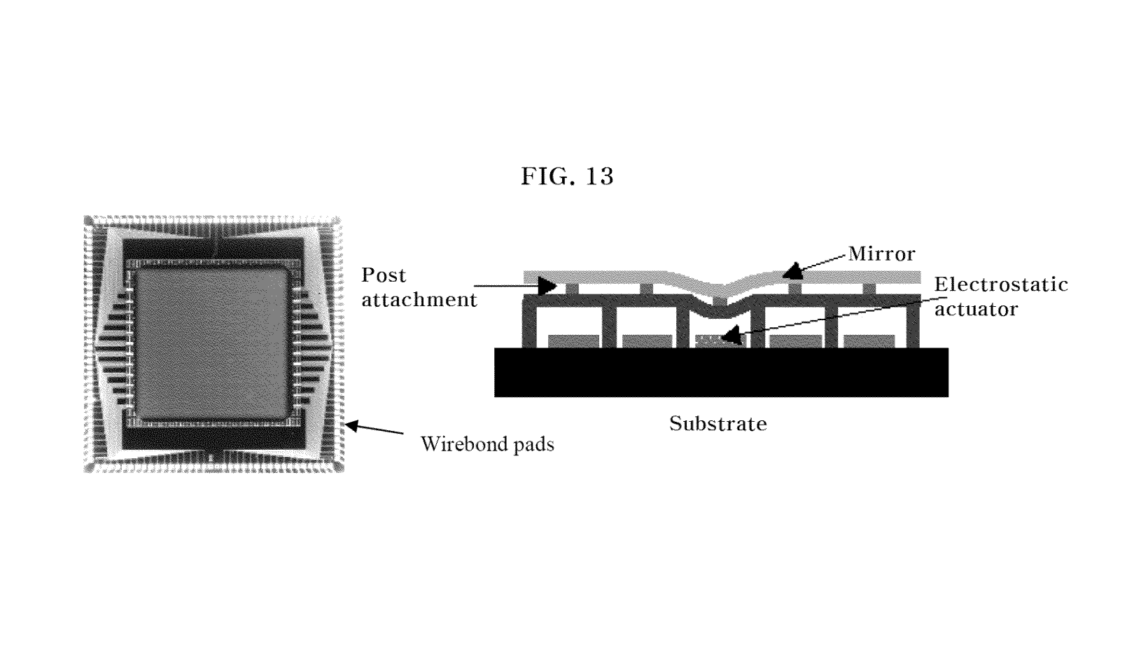

FIG. 13 is show one example of MEMS micro mirror. In FIG. 13, the left Image shows Boston Micromachines Corporation MEMS die and right Image shows that a cross-sectional illustration of a 1×5 array of the electrostatically actuated MEMS mirror. The device structure consists of actuator electrodes underneath a double cantilever flexure, which is electrically isolated from the electrodes and maintained at a ground potential. The electrostatic actuators are arranged in a square grid and the flexible mirror surface is connected to the center of each actuator through a small attachment post that translates the actuator motion to a mirror surface deformation.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. A wavelength conversion laser system, comprising:
an optical amplifier which emit a light with wavelength range and amplify the light;
an optical condenser that condenses the light emitted from the optical amplifier;
a diffraction grating plate that induces wavelength components of the light having passed through the optical condenser in different directions; and
an optical very large scale integration (VLSI) processor that causes a specific wavelength of the light of the induced wavelength components to be returned to the diffraction grating plate, wherein the specific wavelength of the light from the diffraction grating plate pass through the optical condenser and is amplified by the optical amplifier.

2. The wavelength conversion laser system of claim 1, the optical amplifier is optical semiconductor amplifier or optical fiber amplifier.

3. The wavelength conversion laser system of claim 1, wherein the optical very large scale integration (VLSI) processor is replaced by MEMS mirror array.

4. A wavelength conversion laser system, comprising:
a light source;
an optical condenser that condenses light emitted from the light source;
a diffraction grating plate that induces wavelength components of the light having passed through the optical condenser in different directions;
an optical very large scale integration (VLSI) processor that causes a specific wavelength of the light of the induced wavelength components to be returned to the light source; and
an optical coupler that is installed between the light source and the optical condenser and splits the light returned from the optical VLSI processor.

5. The wavelength conversion laser system of claim 4, wherein the optical coupler includes one input port and two output ports, wherein the input port is connected to the optical condenser, one of the two output ports is connected to a light-emitting diode (LED), and the other of the two output ports functions as an actual output part.

6. The wavelength conversion laser system of claim 4, wherein the optical coupler includes one input port and two output ports, wherein the input port is connected to the optical condenser, one of the two output ports is connected to a plurality of light-emitting diodes (LEDs) having different wavelength ranges, and the other of the two output ports functions as an actual output part.

7. The wavelength conversion laser system of claim 4, wherein the light source is a super luminescent diode (SLD).

8. The wavelength conversion laser system of claim 4, wherein the light source is an erbium doped fiber laser (EDFL).

9. The wavelength conversion laser system of claim 4, wherein the optical very large scale integration (VLSI) processor is replaced by MEMS mirror array.
